(19) United States
(12) Patent Application Publication
(10) Pub. No.: US 2026/0196971 A1
(43) Pub. Date: Jul. 9, 2026

(54) SINGLE GATE BIAS POWER AMPLIFIER CIRCUIT WITH TAILORED THRESHOLD TRANSISTORS AND MANUFACTURING METHODS THEREOF

(71) Applicant: AGNIT SEMICONDUCTORS PRIVATE LTD, BANGALORE (IN)

(72) Inventors: DIGBIJOY NEELIM NATH, Bangalore (IN); HAREESH CHANDRASEKAR, Bangalore (IN)

(21) Appl. No.: 19/291,654

(22) Filed: Aug. 6, 2025

(30) Foreign Application Priority Data
Jan. 8, 2025 (IN) 202541001775

(51) Int. Cl. H03F 1/02; H03F 3/21; H10D 30/47; H10D 84/01; H10D 84/82

(52) U.S. Cl. CPC H03F 1/0288; H03F 3/211; H10D 30/471; H10D 84/0123; H10D 84/82

(57) ABSTRACT

The invention relates to an innovative power amplifier (PA) circuit design aimed at enhancing efficiency and simplifying circuit complexity for modern wireless communication systems. This design employs a hybrid architecture that combines a main amplifier and an auxiliary amplifier, which work together to optimize performance across a broad range of output power levels. A key feature of the design is the use of a single gate bias voltage, applied to both amplifiers, eliminating the need for separate bias supplies and reducing overall circuit complexity. The amplification circuitry includes a main amplifier with a first transistor, an auxiliary amplifier with a second transistor, and a common gate bias supply. The transistors are fabricated either on a single wafer or separate wafers, with tailored threshold voltages to ensure optimal performance and efficient operation.

### FIELD OF THE INVENTION

The invention relates to semiconductor device technology, specifically to methods and systems for designing and manufacturing power amplifier circuitry.

### BACKGROUND OF THE INVENTION

Unless otherwise indicated herein, approaches described in this section are not prior art to the claims listed below and are not admitted as prior art by inclusion in this section.

Power amplifier circuits (PAs) are integral components in any wireless transmit-receive system, including cell phone base stations, handsets, Wi-Fi routers, military and meteorological radars, satellites, and electronic warfare systems. These circuits boost the strength of the wireless signal before transmission, directly impacting the system's overall performance and efficiency. Given that PAs are one of the most power-hungry components in wireless communication devices, maximizing their efficiency is essential to extend battery life and reduce energy consumption. However, a critical challenge in PA circuit design is balancing efficiency and linearity; increasing efficiency often leads to reduced linearity, resulting in signal distortion and compromised fidelity.

The Doherty Power Amplifier (DPA) builds upon traditional power amplifier designs by using a dual-amplifier architecture to optimize efficiency and linearity, addressing the inherent trade-offs found in conventional PAs.

DPA offers a solution to this trade-off between efficiency and linearity. A DPA utilizes two distinct power amplifiers that work in tandem to achieve high efficiency without significantly compromising signal linearity. This is accomplished by combining a "main" amplifier, typically operated in Class AB mode (main amplifier also known as carrier amplifier), with an "auxiliary" amplifier, generally operated in Class C mode (auxiliary amplifier also known as peaking amplifier). The unique architecture allows the DPA to maintain better linearity and higher efficiency across varying input signal levels. As a result, DPAs are widely adopted in modern wireless communication infrastructure, particularly in 4G and 5G base stations, where they are often implemented using gallium nitride (GaN) high electron mobility transistor (HEMT) technology.

However, conventional Doherty Power Amplifiers may not achieve the desired levels of linearity and efficiency due to their reliance on multiple voltage supplies for gate biasing. Specifically, DPA architecture typically requires two separate voltage supplies for the two amplifier's gates to maintain the distinct operating conditions necessary for Class AB and Class C operations. On a semiconductor wafer, such as a GaN HEMT wafer or Silicon wafer, the threshold voltage (Vₜₕ) of the transistors is uniform, creating a need for different gate voltages to ensure optimal performance. This requirement for multiple voltage supplies introduces additional circuit complexity, increases costs, and may degrade overall performance.

Consequently, there is a need for a new approach to power amplifier design, specifically for amplifying RF signals, that can provide improved linearity and efficiency while reducing the complexity and cost associated with conventional DPAs.

### OBJECTIVE OF THE INVENTION

The principal objective of this invention is to simplify the design of a Power Amplifier circuit by enabling the use of a single gate bias voltage supply for all amplifier stages, thereby reducing circuit complexity and cost.

Another objective of this invention is to provide a method for tailoring (or engineering) the threshold voltages of transistors either on a single semiconductor wafer, such as GaN HEMT or using two different semiconductor wafers, to achieve the required operating conditions for each amplifier stage under a single gate bias.

Another objective of this invention is to enhance the efficiency and linearity of the PA by optimizing the operation of its amplifiers through precise control of the transistors' threshold voltages, minimizing distortion and maintaining signal fidelity.

A further objective of this invention is to offer a cost-effective and scalable solution for manufacturing Doherty Power Amplifiers with improved performance, enabling their use in various applications such as wireless communication base stations, radar systems, and satellite communication.

### SUMMARY OF THE INVENTION

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

The invention introduces an approach to designing Power Amplifiers Circuit that simplifies their architecture by utilizing a single gate bias voltage supply. Traditional Doherty amplifiers require two separate voltage supplies for the gate biasing of each amplifier, adding complexity and cost to the system. This invention addresses this challenge by employing transistors with different threshold voltages (Vₜₕ) on the same semiconductor wafer or on different semiconductor wafers or devices, enabling the use of a single gate bias voltage to achieve the desired operating conditions for both amplifiers. This innovation reduces the need for additional circuitry, simplifies the design, and lowers the overall manufacturing costs.

To achieve this, the invention proposes methods to tailor the threshold voltages of transistors either on a single wafer or separate wafers. One method involves a gate recess etch, which partially removes the barrier layer of the transistor, resulting in a less negative threshold voltage. The depth of the etch can be precisely controlled to obtain the desired Vₜₕ. The other method involves using a thin gate dielectric layer, such as silicon nitride (SiNₓ) or aluminum oxide (Al₂O₃), which makes the threshold voltage more negative by modifying the electric field characteristics. These techniques enable the creation of transistors with different Vₜₕ values on the same wafer or on separate wafers, facilitating their use in a single-gate-bias PA configuration.

Furthermore, the invention provides a cost-effective and scalable manufacturing process for fabricating transistors with different Vₜₕ values on a single wafer. The process includes standard semiconductor fabrication steps, such as lithography, etching, and metal deposition, with specific modifications to the gate stack module. This approach ensures compatibility with existing semiconductor fabrication techniques and equipment, allowing for easy adoption and integration into current manufacturing workflows without the need for significant retooling or new investments.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciated that the drawings are not necessarily in scale as some components may be shown to be out of proportion than the size in actual implementation in order to clearly illustrate the concept of the present disclosure.

FIG. 1 illustrates one way for tailoring the threshold voltage (Vth) on a single semiconductor wafer such as GaN HEMT through gate recess etching of the barrier layer (100). The figure is divided into two parts:

FIG. 1(A) shows a standard GaN HEMT with an unrecessed gate, where the device operates with its natural threshold voltage (Vth).

FIG. 1(B) depicts a GaN HEMT with a recessed gate, where a portion of the barrier layer under the gate has been etched away. The recessed gate structure reduces the negative value of the threshold voltage, effectively adjusting the device’s turn-on characteristics.

FIG. 2 illustrates another method for tailoring the threshold voltage (Vth) on a semiconductor wafer, such as GaN wafer, by using a gate dielectric (200). The figure is divided into two parts:

FIG. 2(A) shows a standard GaN HEMT without a gate dielectric, where the transistor operates at its normal threshold voltage.

FIG. 2(B) shows a GaN HEMT with a gate dielectric layer added. This layer causes the threshold voltage to become more negative compared to the standard HEMT, as per the preferred embodiment of the invention.

FIG. 3 illustrates the novel Power Amplifier design, which features transistors with different threshold voltages while operating under the same gate bias voltage (300).

FIG. 4 illustrates the fabrication process for recessed - gate HEMT (400). The fabrication process comprises:

FIG. 4(A) depicts a GaN wafer with SiNx passivation after Source/Drain metallization and mesa isolation, according to one embodiment of the present invention.

FIG. 4(B) illustrates the lithography process used to selectively pattern and define the gate foot and recess etch region, in accordance with an embodiment of the invention.

FIG. 4(C) shows the exposure and development of photoresist or e-beam resist after lithography, according to one embodiment of the present invention.

FIG. 4(D) depicts the Fluorine plasma (eg: SF6 or CF4 plasma) to selectively etch the SiNx passivation layer according to the exemplary embodiment of the present invention.

FIG. 4(E) shows the SiNx layer completely etched in selective areas where the gate will be defined, with the etch stopping at the barrier layer, in accordance with an embodiment of the invention.

FIG. 4(F) illustrates the use of chlorine-based plasma (e.g., BCl3/Cl2 and O2 plasma) to recess etch the barrier layer (, e.g., AlGaN), in accordance with an embodiment of the invention.

FIG. 4(G) shows the deposition of a gate metal stack (e.g., nickel and gold) across the wafer using e-beam evaporation or sputtering, in accordance with an embodiment of the invention.

FIG. 4(H) illustrates the lift-off process, where the wafer is subjected to a chemical solution that removes the photoresist or e-beam resist, according to a preferred embodiment of the present invention.

FIG. 4(I) illustrates the lithography process, including spin coating resist and defining a pattern for the gate field-plate, according to one embodiment of the present invention.

FIG. 4(J) shows the exposure and development process used to define the pattern, according to the exemplary embodiment of the present invention.

FIG. 4(K) illustrates the metal evaporation process (e.g., gold with a thickness ranging from 100 to 400 nm) across the wafer, according to an embodiment of the present invention.

FIG. 4(L) depicts the lift-off process, as defined in FIG. 4(H), according to an embodiment of the present invention.

Persons skilled in the art will appreciate that elements in the figures are illustrated for simplicity and clarity and may have not been drawn to scale. For example, the dimensions of some of the elements in the figure may be exaggerated relative to other elements to help to improve understanding of various exemplary embodiments of the present disclosure.

Throughout the drawings, it should be noted that reference numbers are used to depict the same or similar elements, features, and structures.

### DETAILED DESCRIPTION OF THE INVENTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings but are merely used by the inventor to enable a clear and consistent understanding of the invention. Accordingly, it should be apparent to those skilled in the art that the following description of exemplary embodiments of the present invention are provided for illustration purposes only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic is intended to provide.

The figures discussed below, and the various embodiments used to describe the principles of the present disclosure in this patent document are by way of illustration only and should not be construed in any way that would limit the scope of the disclosure. Those skilled in the art will understand that the principles of the present disclosure may be implemented in any suitably arranged system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly stated otherwise. A set is defined as a non-empty set including at least one element.

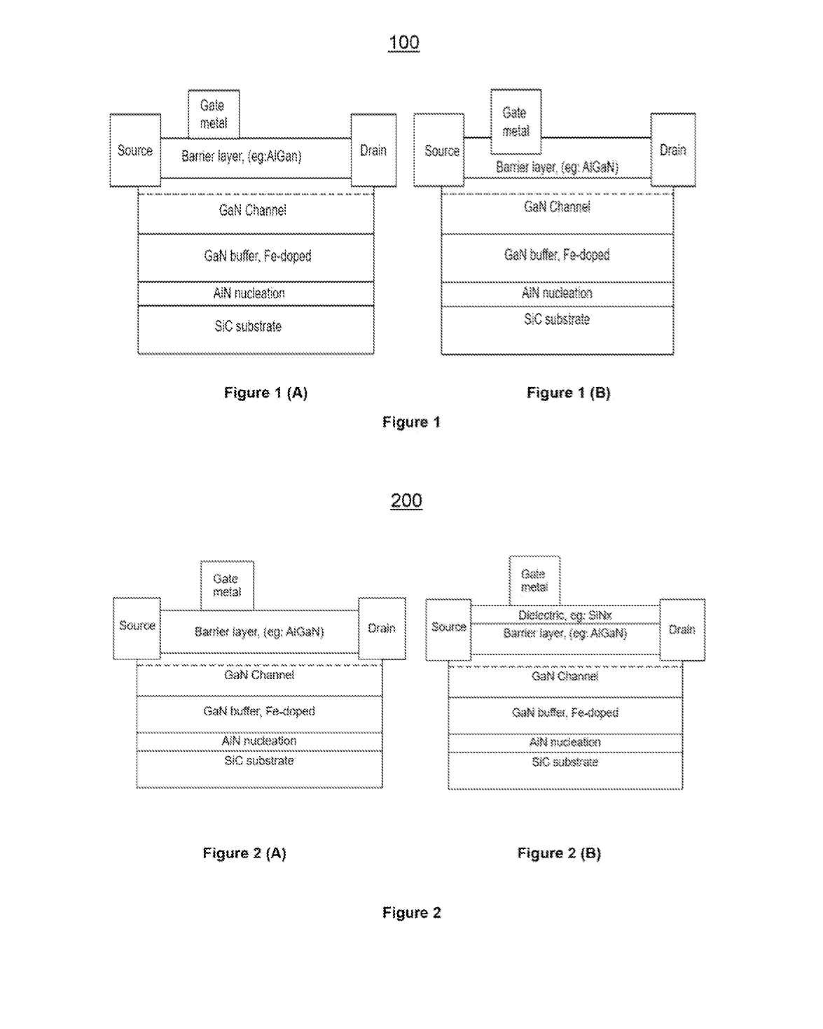

FIG. 1 illustrates one method for tailoring the threshold voltage (Vₜₕ) of Gallium Nitride High Electron Mobility Transistors (GaN HEMTs) on a single or on separate semiconductor wafers (100). This technique, known as the gate recess, etch of the barrier, enables the customization of Vₜₕ values across the wafer, thereby enhancing transistor performance for various high-power and high-frequency applications.

A high-electron-mobility transistor (HEMT), also referred to as a heterostructure field-effect transistor (HFET) or modulation-doped field-effect transistor (MODFET), is a type of field-effect transistor comprising a heterojunction between two materials with differing band gaps, utilized as the channel in place of a doped region typically used in metal-oxide-semiconductor field-effect transistors (MOSFETs). A commonly employed material combination consists of gallium arsenide (GaAs) and aluminium gallium arsenide (AlGaAs); however, alternative material combinations may be employed depending on the specific application. Devices with increased indium content exhibit improved high-frequency performance, while gallium nitride (GaN)-based HEMTs have garnered significant interest for their superior high-power performance.

Similar to other field-effect transistors, HEMTs may be employed in integrated circuits for digital switching applications, functioning as on-off switches. Additionally, HEMTs may be utilized as amplifiers, enabling the amplification of large currents via a small control voltage. The current-voltage characteristics inherent to field-effect transistors facilitate both of these functions. Furthermore, HEMTs are capable of operating at higher frequencies than conventional transistors, including at millimetre-wave frequencies, thereby making them suitable for use in high-frequency applications such as cellular communications, satellite television receivers, voltage conversion systems, and radar systems. HEMTs find extensive application in satellite receivers, low-power amplifiers, and various defence industry applications.

A Gallium Nitride High Electron Mobility Transistor (GaN HEMT) is a type of field-effect transistor that uses GaN as the semiconductor material, known for its high power, high efficiency, and high-frequency capabilities. Due to GaN’s wide bandgap, these transistors can operate at higher voltages, temperatures, and frequencies than traditional silicon-based devices. GaN HEMTs are widely used in applications like telecommunications (5G networks, satellite communication), power electronics (inverters, power converters), and defense (radar systems, electronic warfare). Their high electron mobility, thermal conductivity, and efficiency make them ideal for high-performance systems, although they are generally more expensive to produce than silicon-based counterparts.

In one embodiment, FIG. 1(A) depicts the standard GaN HEMT configuration. In this design, the transistor features a uniform barrier layer beneath the gate, with consistent thickness and material properties throughout the wafer. This results in a uniform threshold voltage (Vₜₕ), typically around -3 V, determined by the inherent properties of the materials and the dimensions of the device. While this configuration simplifies the manufacturing process, it limits the ability to adjust the transistor’s performance for specific applications, as all devices on the wafer have the same Vₜₕ value.

FIG. 1(B) introduces an advanced configuration with a recessed gate structure, which is a method for tailoring Vₜₕ. This approach involves selectively etching away a portion of the barrier layer beneath the gate to create a recess. This modification reduces the barrier's thickness in the area directly under the gate, altering the electric field distribution between the gate and the channel. As a result, the threshold voltage becomes less negative, for instance, from -3 V to -2.6 V. This ‘less negative’ threshold voltage depends on the recess depth and other process conditions. This allows the transistor to turn on with a less negative gate voltage, enhancing its responsiveness and suitability for applications requiring different voltage operating ranges.

The recessed gate method offers significant advantages in performance flexibility and circuit design simplification. For applications such as Doherty Power Amplifiers (DPAs), where various amplifiers may need different threshold voltages to operate efficiently at different power levels, this technique enables the use of a single gate bias supply. By achieving multiple Vₜₕ values on the same wafer or different wafers through controlled gate recess etching, the approach optimizes each amplifier’s performance while reducing circuit complexity.

FIG. 2 illustrates another method of tailoring the threshold voltage (Vₜₕ) in GaN HEMTs by incorporating a gate dielectric (200). This technique includes two configurations: the standard HEMT and the Metal-Insulator-Semiconductor HEMT (MISHEMT), each showcasing different approaches to achieving desired Vth values.

In one embodiment, FIG. 2(A) shows the standard GaN HEMT configuration, where the gate metal is in direct contact with the barrier layer semiconductor material, without any insulating layer. In this traditional setup, the electrical characteristics of the HEMT are determined solely by the properties of the AlGaN and GaN material and the physical design of the device. The threshold voltage in this configuration is typically around -3 V, indicating the gate voltage required to switch the transistor from the "off" state to the "on" state. This fixed Vₜₕ limits the operational flexibility of the device, as it necessitates a higher gate voltage to activate the transistor, thus constraining its performance in various applications.

FIG. 2(B) presents the GaN HEMT with a gate dielectric layer, such as silicon nitride (SiNₓ) or aluminium oxide (Al₂O₃) or other relevant dielectric, placed between the gate metal and the semiconductor barrier. This Metal-Insulator-Semiconductor HEMT (MISHEMT) design introduces an insulating layer that modifies the interaction between the gate and the semiconductor. As a result, the threshold voltage becomes more negative compared to the standard configuration. For instance, while a standard HEMT might have a Vₜₕ of -3 V, the addition of the gate dielectric can achieve a Vₜₕ of approximately -3.5 V and this value depends on the thickness as well as the type of the dielectric used below the gate metal. This more negative Vₜₕ means that the device can turn on with a lower gate voltage (more negative), enhancing its responsiveness and performance for specific applications.

The incorporation of a gate dielectric in a MISHEMT allows for precise control over the threshold voltage. By varying the thickness of the dielectric layer, designers can finely tune the Vₜₕ to meet specific operational requirements. Thicker dielectrics generally result in a more negative Vₜₕ, providing improved control over the transistor's switching characteristics. This level of precision is particularly advantageous in applications like power amplifiers, where different transistors may need to operate efficiently under varying conditions. The gate dielectric method thus represents a valuable approach for optimizing GaN HEMTs for diverse high-power and high-frequency applications.

The circuitry, wherein the threshold voltage of each transistor is tailored by applying a gate dielectric layer, with the thickness of the dielectric layer ranging from approximately 1 nm to 10 nm after recess etching of the barrier. Alternatively, the threshold voltage can be tailored by applying the gate dielectric layer without any recess etching of the barrier, with the dielectric layer's thickness ranging from approximately 1 nm to 30 nm. These precise adjustments to the gate dielectric thickness enable the optimization of the threshold voltage for each transistor, ensuring the efficient operation of the power amplifier.

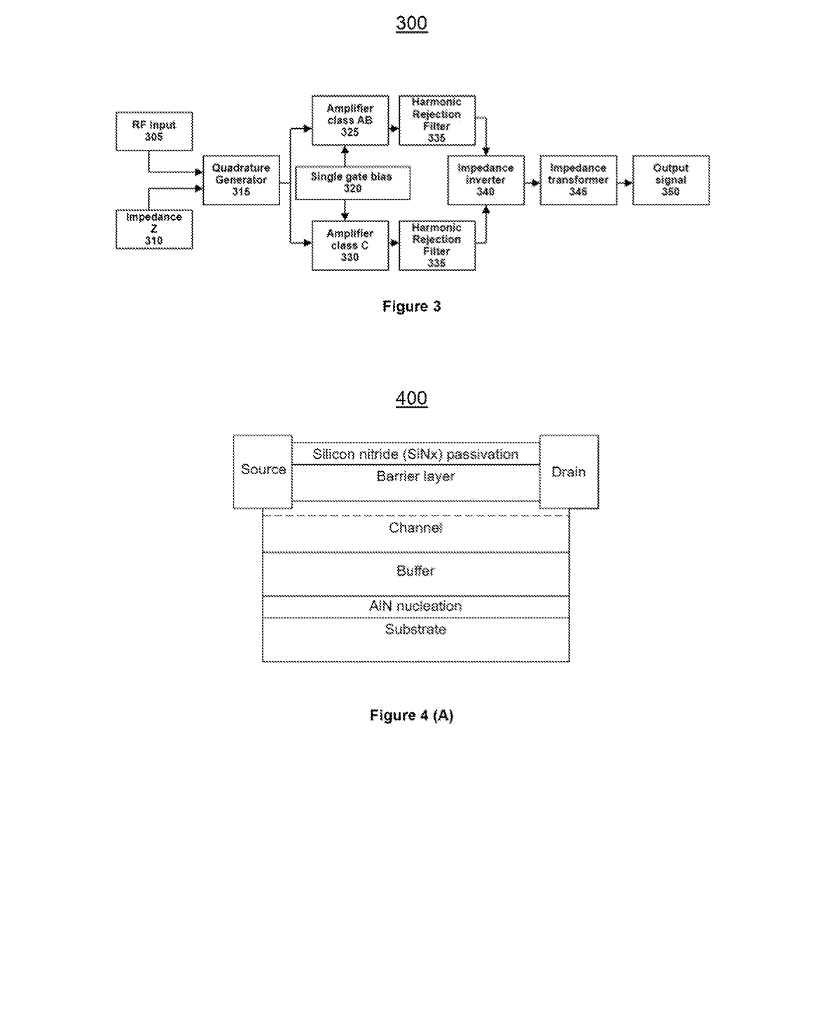

FIG. 3 illustrates an innovative power amplifier (PA) design that efficiently amplifies radio frequency (RF) input signals while significantly reducing circuit complexity, providing improved performance for modern wireless communication systems (300). The design employs a unique architecture that combines both linear and efficient amplification in a single system, allowing for the simultaneous optimization of power efficiency and linearity over a wide output power range.

In one embodiment, the PA circuit begins with an RF input signal (305), which is routed through an impedance matching element (Z) (310). The impedance matching ensures that the input impedance is matched to the amplifier circuit, typically 50 ohms. This impedance matching is essential to maximize power transfer and minimize signal reflections that could otherwise degrade performance. Following impedance matching, the signal is directed to a quadrature generator (315), which divides the input signal into two components, each with a 90-degree phase shift. The phase-shifted signals are critical for the optimal operation of the Doherty Power Amplifier (DPA) configuration, where a Class AB amplifier (325) and a Class C amplifier (330) operate in phase opposition. This configuration improves the PA's performance across a broad range of output power levels.

The phase-shifted signals are processed by the respective amplifiers. The Class AB amplifier (325) uses a transistor with a threshold voltage (Vth) of approximately -3.0 V, which is biased with a common gate voltage of -2.6 V, slightly above its threshold voltage. This biasing allows the transistor to conduct for most of the signal cycle, thereby providing linear amplification with moderate efficiency. This design strikes a balance between linearity and efficiency, making it suitable for handling low to moderate power levels.

Conversely, the Class C amplifier (330) uses a transistor with a lower threshold voltage of approximately -2.4 V, prioritizing efficiency over linearity. The common gate voltage of -2.6 V keeps the transistor in an off state during low and mid-power levels, and it only becomes active when the output power reaches higher levels. The Class C amplifier operates at significantly higher efficiency (80-90%) during peak power conditions, which is beneficial in high-power scenarios. While Class C amplifiers are less linear, the reduction in linearity can be addressed through signal correction techniques, making it suitable for high-power output where efficiency is critical.

A key feature of the disclosed design is the use of a single gate bias voltage of -2.6 V applied to both the Class AB and Class C transistors. This approach eliminates the need for separate biasing circuits, thereby simplifying the overall design while improving efficiency across a wide output power range. By utilizing a common gate voltage, both amplifiers operate under coordinated biasing conditions, optimizing performance while reducing circuit complexity. To ensure optimal operation, the threshold voltages of the transistors are carefully tailored to be distinct, ensuring each amplifier operates efficiently under the same gate bias.

Once the signal is amplified, it passes through a harmonic rejection filter (335) to remove unwanted harmonics, such as the second and third harmonics, which could distort the signal. For instance, if the fundamental frequency is 2.6 GHz, the filter effectively suppresses harmonics at 5.2 GHz and 7.8 GHz, ensuring that the output signal remains clean and suitable for transmission. The filtered signal is then routed through an impedance inverter (340), which dynamically adjusts the load impedance according to the output power level. At lower power levels, the impedance inverter increases the impedance seen by the Class AB amplifier, improving its efficiency. As the output power increases and the Class C amplifier becomes active, the impedance inverter adjusts to balance the load sharing between the two amplifiers, ensuring maximum efficiency across the entire power range.

Finally, the amplified and impedance-matched signal passes through an impedance transformer (345), which ensures that the output impedance is matched to the desired transmission line impedance, typically 50 ohms. This impedance matching guarantees that the amplified signal is transmitted efficiently to the antenna or transmission line, minimizing power loss and reflection.

The PA design described herein significantly improves efficiency when compared to traditional architectures. At a 6 dB back-off (where the output power is reduced to 25% of the maximum output), the PA achieves efficiencies ranging from 50% to 60%. At peak power, where both the Class AB and Class C amplifiers are fully engaged, efficiency can exceed 70%, making this design highly suitable for modern wireless communication systems, such as 4G and 5G, which require both high efficiency and linearity.

The transistors utilized in this power amplifier design may be fabricated on either a single semiconductor wafer or separate semiconductor wafers. When fabricated on separate wafers, the Class AB transistor (first transistor) is typically formed on a gallium nitride (GaN) wafer which could be on any substrate such as Silicon Carbide (SiC), Sapphire, Diamond, Silicon or Gallium Nitride (GaN), which is chosen for its high electron mobility and thermal conductivity, making it ideal for handling the high-power demands of Class AB amplification. The Class C transistor (second transistor), optimized for high efficiency, can be fabricated on a silicon wafer or GaN or any other suitable semiconductor material, depending on the desired characteristics of the amplifier. The substrate of the GaN wafer can be any substrate, Silicon Carbide (SiC), Sapphire, Diamond, Silicon or Gallium Nitride (GaN).

Alternatively, both transistors can be fabricated on a single semiconductor wafer, such as a GaN on any substrate such as Silicon Carbide, Sapphire, Diamond, Silicon or Gallium Nitride. This integration on a single wafer helps reduce the overall size of the PA circuit and simplifies the manufacturing process. The integration further enhances the performance by enabling better thermal management and reducing parasitic losses.

The threshold voltages of the transistors in the Class AB and Class C amplifiers are carefully tailored to be distinct, ensuring that each amplifier operates optimally under the same gate bias voltage. This tailored approach ensures that the Class AB amplifier remains efficient at low to moderate output power levels, while the Class C amplifier achieves high efficiency at higher output power levels. The distinct threshold voltages are achieved through precise semiconductor fabrication techniques, such as recess etching of the barrier layer or adjustments to the gate dielectric thickness, which enable the transistors to operate effectively within their respective amplification modes. By fine-tuning the threshold voltages, both amplifiers can work in harmony, optimizing the overall performance of the PA system.

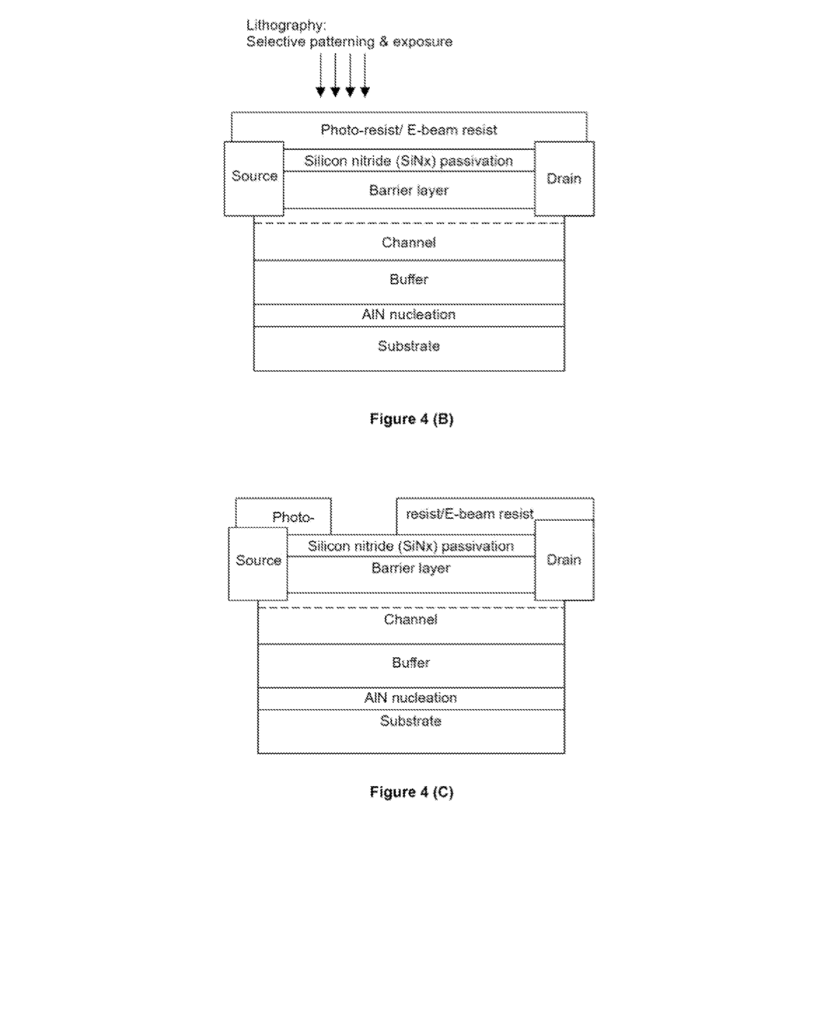

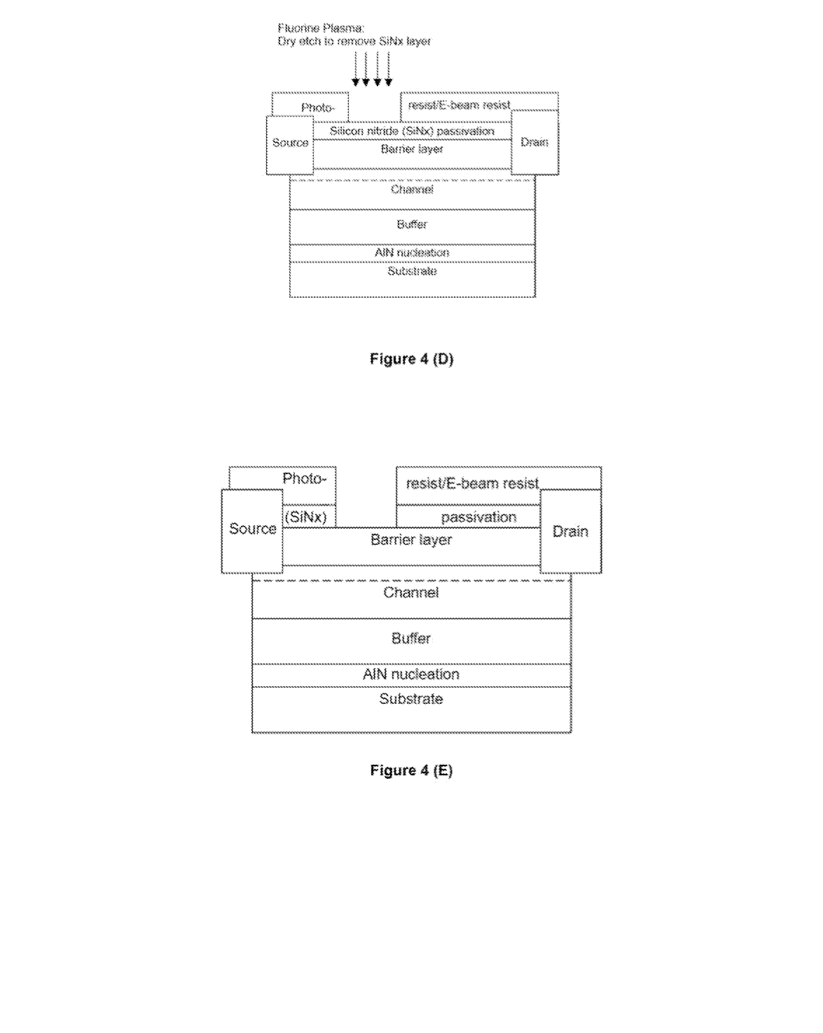

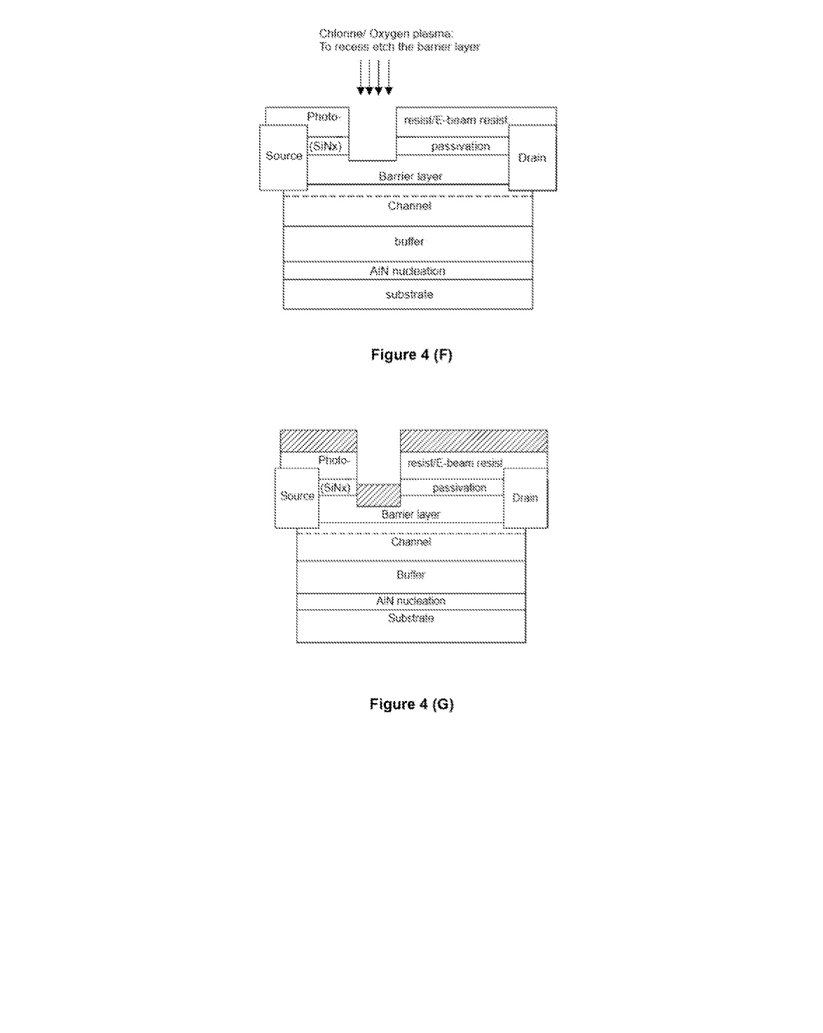

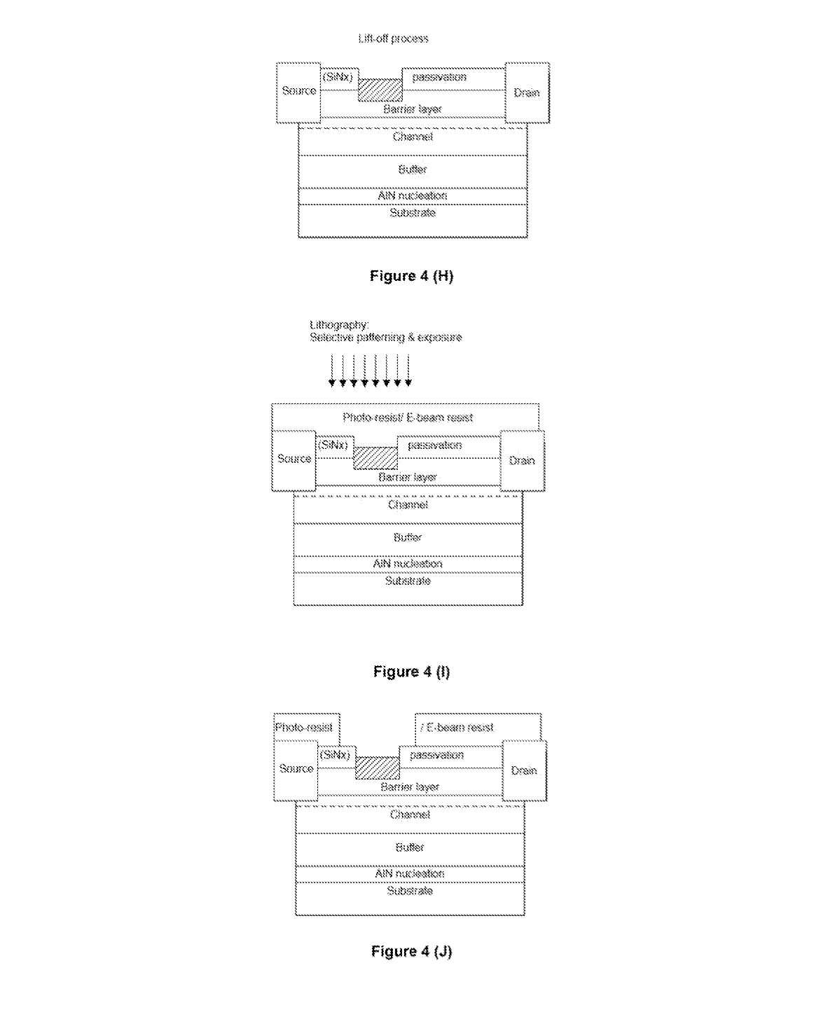

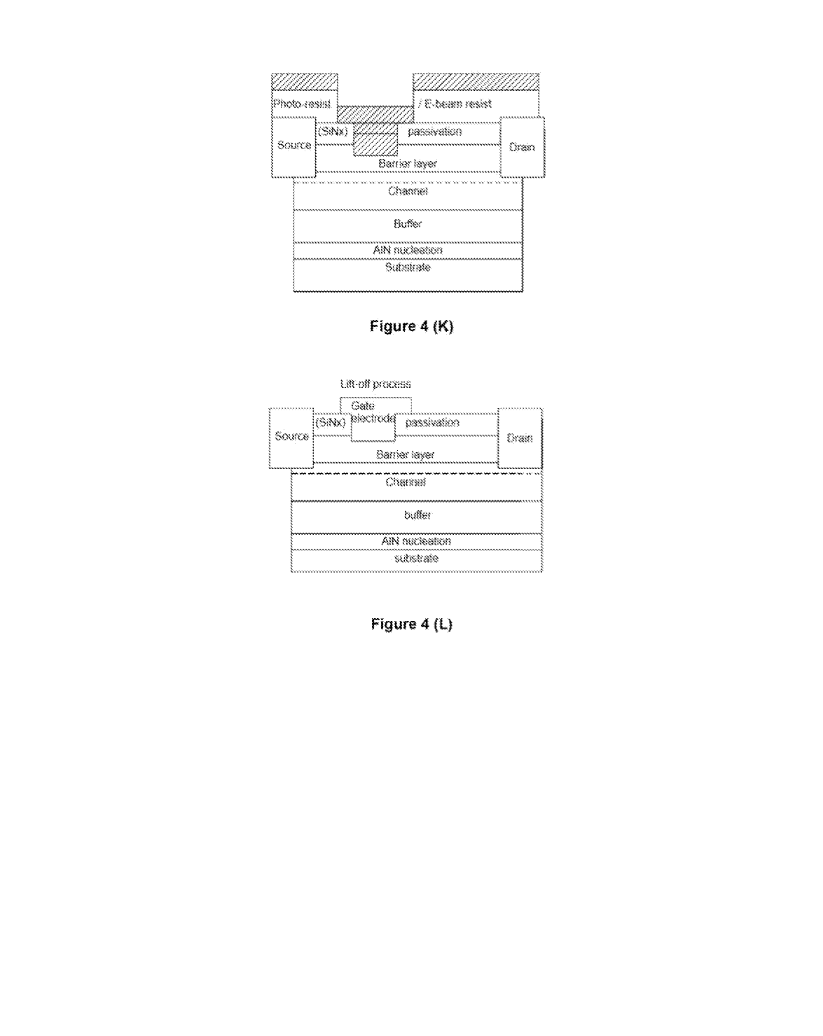

FIG. 4 provides a detailed overview of the fabrication process of gate stack of Gallium Nitride High Electron Mobility Transistors (GaN HEMTs), outlining the various layers and components essential for the device’s construction (400). The figure illustrates the key modules involved in the HEMT fabrication process, including Ohmic contacts, mesa isolation, passivation, gate stack formation, field-plate integration, bond pads, air-bridges, and source-vias.

In the proposed fabrication method, two types of HEMTs are co-fabricated on the same wafer: Type 1 and Type 2. Type 1 HEMT has a threshold voltage (Vₜₕ) determined by the thickness of the barrier layer, while Type 2 HEMT features a recessed gate, resulting in a threshold voltage that is less negative than that of Type 1. Although the general process is similar for both types, the gate stack formation differs. Specific steps for creating the recessed gate in Type 2 HEMT are detailed in FIGS. 4A to 4F. During this process, the regions designated for Type 1 HEMTs are protected with a layer of photoresist or e-beam resist to prevent any cross-contamination or interference.

In one embodiment, FIG. 4A provides an illustration of Step 1 in the fabrication process of GaN High Electron Mobility Transistors (HEMTs). This step focuses on the condition of the GaN wafer after the application of SiNx passivation following source and drain metallization and mesa isolation.

The GaN wafer is shown with a layer of silicon nitride (SiNₓ) passivation applied on its surface. This passivation layer is critical for protecting the device and ensuring its optimal performance. The process begins with the metallization of the source and drain regions of the HEMT. This involves depositing metal contacts to create the necessary electrical connections for current flow through the device. Subsequently, mesa isolation is performed to define distinct regions on the wafer, separating different HEMTs and minimizing electrical interference between them.

After these initial steps, the SiNₓ passivation layer is applied. SiNₓ serves multiple functions: it acts as a protective coating to shield the underlying semiconductor layers from environmental contaminants, moisture, and other potential sources of degradation. Additionally, it helps to reduce surface states that can trap charge carriers, which is crucial for maintaining the high-performance characteristics of the HEMT.

FIG. 4B illustrates Step 2 of the fabrication process for the gate stack of HEMTs, focusing on the use of lithography to pattern the wafer selectively. This step is pivotal for defining the regions where the gate foot will be formed and where the recess etching will occur, ensuring precise control over the device's characteristics.

Lithography is employed to transfer a detailed pattern onto the wafer's surface. This pattern dictates the specific areas where the gate electrode and the recess etching will take place. By accurately defining these regions, lithography sets the stage for subsequent etching processes, which are essential for creating the desired gate structure and modifying the barrier layer.

The lithography process begins with the application of a photoresist material onto the wafer. This photoresist is sensitive to light and will change its solubility depending on exposure to specific wavelengths. A mask with the intended pattern is then aligned and placed over the photoresist-coated wafer. The wafer is exposed to light, which passes through the mask and interacts with the photoresist. Depending on whether a positive or negative photoresist is used, the exposed areas will either become more soluble or less soluble.

Following the exposure, the wafer undergoes a development process where the soluble portions of the photoresist are removed. This leaves behind a patterned photoresist layer that accurately represents the regions for the gate foot and recess etch. The pattern ensures that only the designated areas of the wafer are altered during the subsequent etching steps, precisely defining where the gate electrode and recess will be formed.

The lithographic patterning is crucial for the success of the fabrication process. It ensures that the gate structure is precisely defined, which is essential for achieving the desired electrical characteristics and performance of the HEMT. The accuracy of the pattern directly affects the dimensions and placement of the gate structure, influencing the overall functionality and efficiency of the HEMT devices.

FIG. 4C depicts Step 3 of the fabrication process for the gate stack in HEMTs, which involves the exposure and development of the photoresist or e-beam resist after the initial lithography. This critical step is crucial for translating the lithographic pattern onto the semiconductor wafer with high precision.

Following the lithography step, the wafer coated with photoresist or e-beam resist is subjected to exposure. For photoresist, this involves illuminating the wafer with light through the mask that bears the desired pattern. The exposure alters the chemical properties of the photoresist, making the exposed areas either more soluble (in the case of positive photoresist) or less soluble (in the case of negative photoresist). For e-beam resist, a focused electron beam directly writes the pattern onto the resist. This method provides high-resolution patterns but is generally slower compared to photolithography. The choice between photoresist and e-beam resist depends on the required resolution and fabrication speed.

After exposure, the wafer is processed with a developer solution tailored to the type of resist used. This step removes the soluble portions of the photoresist or e-beam resist, leaving behind a patterned layer that mirrors the areas intended for gate foot and recess etching. The development process is critical for achieving the desired pattern accuracy and fidelity, which are vital for the success of subsequent etching processes.

Accurate exposure and development of the resist are essential for defining the gate foot and recess etch regions with precision. Errors or inconsistencies in this step can lead to misalignment or incorrect dimensions, which could adversely impact the performance and reliability of the HEMT device. The patterned resist acts as a protective barrier during the etching process, ensuring that only the intended areas of the underlying material are affected, thereby maintaining the integrity and functionality of the gate structure.

FIG. 4D illustrates Step 4 of the fabrication process for the gate stack in HEMTs, which involves the selective etching of the silicon nitride (SiNx) passivation layer using fluorine plasma. This step is crucial for preparing the wafer for the subsequent recess etching of the barrier layer, ensuring precise patterning and protection of the underlying materials.

The SiNx passivation layer is applied to protect specific areas of the wafer during the fabrication process. However, before the recess etching of the barrier layer can be carried out, it is necessary to remove the SiNx from regions where the gate foot and recess etch will be defined. This selective removal ensures that only the designated areas are exposed for further processing, while the rest of the wafer remains shielded from potential damage.

To achieve selective etching, fluorine plasma is employed. This plasma is generated from gases such as sulfur hexafluoride (SF6) or carbon tetrafluoride (CF4), which are highly reactive with silicon-based materials, including SiNx. The plasma is created by applying a high-frequency electric field to the gas, resulting in ionization and the formation of reactive species capable of etching away the SiNx layer. The choice of fluorine-based gases is due to their effective etching properties and ability to target silicon nitride specifically.

In this step, the wafer is placed in a plasma etching chamber where the fluorine plasma is introduced. The reactive species within the plasma interact with the exposed SiNx areas, selectively etching away the passivation layer. Careful control of the etching parameters is essential to ensure that only the SiNx layer is removed while preserving the integrity of the underlying layers and structures on the wafer. This precision is critical for defining the regions where further etching and processing will occur.

Selective etching of the SiNx passivation layer is a vital step in the fabrication process, as it defines the specific areas where the gate foot and recess etching will take place. Proper control of the etching process is crucial for achieving the desired depth and accuracy, which directly influences the performance and reliability of the final HEMT device. By ensuring that only the intended regions are exposed, the process minimizes the risk of damage to other critical components and maintains the overall quality of the HEMT structure.

FIG. 4E details Step 5 in the fabrication process of the gate stack for HEMTs, focusing on the complete etching of the silicon nitride (SiNx) passivation layer in the specific areas where the gate will be defined. This step is crucial for preparing the wafer for the subsequent recess etching of the barrier layer. Here’s a detailed breakdown of this step:

The main goal of Step 5 is to ensure that the SiNx passivation layer is entirely removed from the areas where the gate structure will be fabricated. This removal is necessary to provide direct access to the underlying barrier layer, which will be critical for the next stage of the fabrication process. By exposing the barrier layer, the wafer is prepared for the recess etching, which will further define the gate structure.

Following the fluorine plasma etching described in Step 4, the etching process continues until the SiNx passivation layer is completely removed from the targeted regions as shown in Step 5. The process is closely monitored to ensure that the etching stops precisely at the barrier layer, which is typically composed of materials such as AlGaN or GaN. Careful control of the etching depth is essential to avoid damaging the barrier layer, as any damage could negatively impact the electrical properties and performance of the HEMT device.

It is critical to stop the etching process at the barrier layer because this layer is fundamental to the operation of the HEMT. The barrier layer is responsible for creating the two-dimensional electron gas (2DEG), which is crucial for the device's performance. If the etching were to penetrate deeper and damage the barrier layer, it could lead to significant changes in the threshold voltage and overall functionality of the HEMT, potentially degrading the device's performance.

By the end of Step 5, the wafer will have exposed regions of the barrier layer where the gate will be defined. These exposed areas are now ready for the subsequent recess etching process, which will further modify the barrier layer to achieve the desired threshold voltage for the HEMT. This step ensures that the wafer is properly prepared for the precise formation of the gate structure and the optimization of device performance.

FIG. 4F illustrates Step 6 in the fabrication process of the gate stack for HEMTs, focusing on the recess etching of the barrier layer, typically composed of AlGaN, using chlorine-based plasma. This step is pivotal for adjusting the threshold voltage (Vₜₕ) of the Type 2 HEMT. Here’s a detailed explanation of this step:

The primary aim of Step 6 is to recess etch the barrier layer to achieve a specific threshold voltage for the Type 2 HEMT. The depth of the recess etch is a crucial factor that influences the electrical characteristics of the device, particularly its Vₜₕ. By controlling the depth of the etch, the device’s electrical properties can be tailored to meet the requirements of various applications.

Chlorine-based plasma is selected for this etching process due to its effectiveness in etching III-Nitride materials, such as AlGaN. The plasma is generated by introducing gases like boron trichloride (BCl3) and chlorine (Cl2) into the etching chamber, often in combination with oxygen (O2) to enhance the etching efficiency. The reactive species in the plasma interact with the AlGaN barrier layer, facilitating precise and controlled etching of the material.

Controlling the depth of the recess etch is essential, as it directly determines the threshold voltage of the Type 2 HEMT. A deeper etch results in a less negative Vₜₕ, compared to a shallower etched gate structure. The etch depth is carefully calculated based on the desired Vₜₕ for the Type 2 HEMT, requiring precise control of the etching parameters, including etch time, chamber pressure, and gas flow rates. Accurate control ensures that the target Vₜₕ is achieved, optimizing the device’s performance for its intended application.

Tailoring the threshold voltage is critical for optimizing the performance of the HEMT. By adjusting the Vₜₕ through recess etching, the device can be tailored for specific needs, such as enhancing linearity, efficiency, or output power. This flexibility allows for the design of HEMTs that are better suited for various RF and microwave applications, making the ability to control Vₜₕ through recess etching a significant advantage in device fabrication.

By the end of Step 6, the barrier layer will have been recessed to the desired depth, effectively setting the threshold voltage for the Type 2 HEMT. This preparation ensures that the device is ready for the subsequent steps in the fabrication process, including the deposition of the gate metal and the final formation of the HEMT structure.

FIG. 4G outlines Step 7 in the fabrication process of the gate stack for HEMTs, which involves the deposition of the gate metal stack across the wafer. This step is crucial for defining the gate electrode of the HEMTs, and it involves the deposition of metal layers using techniques such as e-beam evaporation or sputtering. Here’s a detailed breakdown of this step:

The main goal of Step 7 is to deposit a gate metal stack that will form the gate electrode of the HEMTs. The metal stack typically includes layers of nickel (Ni) and gold (Au), with a total thickness ranging between 20 nm to 100 nm. This gate metal stack is essential for controlling the flow of current in the HEMT channel and influencing the device's electrical characteristics.

The gate metal stack is deposited across the wafer using either e-beam evaporation or sputtering techniques. E-beam evaporation involves heating the metal source material using an electron beam in a vacuum chamber, allowing the metal to evaporate and condense onto the wafer surface. Sputtering, on the other hand, involves bombarding the metal target with ions in a vacuum, causing metal atoms to be ejected and deposited onto the wafer. Both methods are effective for creating thin, uniform metal layers essential for the gate structure.

During this deposition step, the wafer is covered with a layer of photoresist or e-beam resist, which protects the areas of the wafer that are not intended to receive the gate metal. The resist remains in place except for the regions where the gate recess etch has been performed. This protective layer ensures that the gate metal is deposited only on the intended areas, preventing contamination or unwanted deposition on other parts of the wafer.

The thickness of the gate metal stack is critical for ensuring proper gate performance and device reliability. A thickness range of 20 nm to 100 nm is chosen to provide adequate electrical conductivity and mechanical stability for the gate electrode. This thickness ensures that the gate metal can effectively control the channel current while maintaining the structural integrity of the gate contact.

By the end of Step 7, the gate metal stack will be deposited across the wafer, forming the gate electrodes for the HEMTs. The photoresist or e-beam resist layer will protect the non-gate regions, allowing the fabrication process to proceed to the next stages, such as gate patterning and final device processing. This step is critical for establishing the electrical connections necessary for the proper operation of the HEMT devices.

FIG. 4H describes Step 8 in the fabrication process, which involves the lift-off process. This step is essential for removing the photoresist or e-beam resist that covered the wafer during the deposition of the gate metal stack. The lift-off process ensures that the gate metal remains only on the desired locations, specifically the recessed etched areas. Here’s a detailed explanation of this step:

The primary goal of Step 8 is to remove the photoresist or e-beam resist from the wafer after the gate metal stack has been deposited. This process leaves behind the metal only in the regions where it was intended, which are the areas where the gate recess etching was performed. The lift-off step is crucial for defining the final gate structure of the HEMTs and ensuring that the gate metal is precisely located.

To carry out the lift-off process, the wafer is subjected to a chemical solution that effectively dissolves the photoresist or e-beam resist. This chemical solution is selected based on the type of resist used and its chemical properties. For photoresist, common solvents include acetone or specialized photo-resist removers, while e-beam resist may require different solvents such as N-Methyl-2-pyrrolidone (NMP).

The wafer is immersed or exposed to the chemical solution, which softens and strips away the resist material. As the resist is removed, the gate metal stack, which was deposited on top of the resist, is lifted off along with the resist layer, leaving the metal only in the recessed etched areas where it is needed.

Accurate lift-off is essential to ensure that the gate metal remains only in the intended regions, without any residue or unwanted metal in other areas. This precision is critical for achieving the desired electrical characteristics and performance of the HEMT devices. Any residue or misalignment during the lift-off process could impact the functionality and reliability of the final device.

By the end of Step 8, the photoresist or e-beam resist will be completely removed from the wafer, leaving the gate metal stack in place only on the recessed etched areas. This completes the formation of the gate electrode for the HEMTs, allowing the fabrication process to proceed to the next steps, such as finalizing the device structure and performing electrical testing. The lift-off process is crucial for ensuring that the gate metal is accurately positioned and properly defined for optimal device performance.

FIG. 4I illustrates Step 9 in the HEMT fabrication process, which involves lithography to define the pattern for the gate field-plate. This step is integral to creating a gate field-plate structure, a key component that enhances the performance of the HEMT by improving control over the electric field. The process focuses on designing a field-plate that extends beyond the gate recess and overlaps with it, which is essential for optimizing device performance.

The primary objective of Step 9 is to pattern the gate field-plate, also known as a Gamma Gate or Γ-Gate. This field-plate structure is intentionally designed to be slightly wider than the gate recess opening and extends more towards the drain side. The presence of the field-plate is crucial for enhancing electric field control, which directly impacts the performance and stability of the HEMT, especially in high-frequency and high-power applications.

The process begins with the application of a new layer of photoresist onto the wafer through spin coating. This photoresist will later define the gate field-plate pattern. Once the resist is applied, it is exposed to light through a mask that contains the desired field-plate pattern. The pattern is designed to be slightly wider than the gate recess opening and to extend towards the drain side. Following exposure, the wafer undergoes a development process where the soluble parts of the photoresist are washed away, leaving behind the patterned resist layer that defines the gate field-plate structure.

The gate field-plate, or Gamma Gate, plays a significant role in stabilizing the electric field around the gate region. By extending and overlapping with the gate recess, it enhances the control of the electric field distribution, which improves device stability and performance. This structure is essential for high-frequency and high-power operations as it helps in mitigating the impact of potential device breakdown and ensures better overall reliability.

By the end of Step 9, the wafer will feature a patterned resist layer that outlines the gate field-plate structure. This patterned resist layer is crucial for the subsequent metal deposition and the final formation of the gate field-plate, which will contribute to the enhanced performance and functionality of the HEMT device.

FIG. 4J illustrates Step 10 in the HEMT fabrication process, focusing on the exposure and development phases to define the pattern for the gate field-plate. This step is crucial for accurately transferring the desired field-plate pattern onto the wafer, ensuring the proper formation of the gate field-plate structure.

The objective of Step 10 is to create a precise pattern for the gate field-plate using the photo-resist layer applied in the previous step. This patterning process is essential for defining the exact areas where the gate field-plate metal will be deposited, impacting the overall performance of the HEMT device.

In this phase, the wafer, which is coated with photoresist, is subjected to exposure through a mask that contains the field-plate pattern. The exposure can be done using either ultraviolet (UV) light (for photoresist) or an electron beam (for e-beam resist). The mask blocks certain areas of the light or electrons, allowing only specific regions of the photoresist to be exposed. This exposure changes the solubility of the photoresist in the exposed areas, based on whether a positive or negative photoresist is used.

After exposure, the wafer undergoes a development process where the soluble parts of the photoresist are removed using a developer solution. This leaves behind a patterned resist layer that outlines the gate field-plate design. The accuracy of this pattern is crucial for ensuring that the gate field-plate is correctly formed and aligned with the gate recess.

The successful exposure and development in Step 10 are essential for defining the gate field-plate pattern with high precision. Any errors in this step can lead to misalignment or incorrect dimensions, which could adversely affect the device's performance. The patterned resist serves as a protective layer during subsequent metal deposition, ensuring that only the intended areas receive the gate field-plate material.

By the end of Step 10, the wafer will have a precisely patterned resist layer that defines the areas where the gate field-plate metal will be deposited. This pattern will ensure that the gate field-plate is formed correctly, contributing to the improved performance and functionality of the HEMT device in its final configuration.

FIG. 4K illustrate the focus is on the evaporation of a metal layer, such as gold, across the wafer. This step is essential for forming the gate field-plate, which plays a critical role in the performance of the HEMT device. The objective is to deposit a metal layer with a thickness ranging from 100 to 400 nm, targeting the regions defined by the photo-resist pattern applied in the previous steps.

The metal evaporation process begins with the preparation of the wafer, which is coated with the patterned photoresist. The resist still covers all regions of the wafer except the areas where the gate field-plate is to be formed. The wafer is placed in an evaporation chamber where a metal source, such as gold, is heated until it vaporizes. The metal vapor then travels across the chamber and condenses onto the exposed regions of the wafer, forming a thin, uniform layer.

The deposition of the metal layer is carefully controlled to ensure the correct thickness and uniformity. This metal layer will form the gate field-plate structure, which is crucial for improving the electric field control around the gate area. The gate field-plate enhances the stability and performance of the HEMT device by optimizing the electric field distribution, which is essential for high-frequency and high-power applications.

At the end of Step 11, the wafer will have a metal layer deposited on the regions defined by the photo-resist pattern. This metal layer creates the gate field-plate structure. The resist still covers the remaining areas of the wafer, protecting them from metal deposition. The next step will involve the lift-off process to remove the remaining photoresist, leaving the gate field-plate intact and ready for further processing.

FIG. 4L illustrates Step 12, which involves the lift-off process as previously outlined in Step 8. This step is essential for finalizing the formation of the gate field-plate by removing the remaining photoresist and revealing the metal structure. The result of this process is that the gate metal becomes thickened, widened, and effectively functions as a field-plate.

The lift-off process begins by subjecting the wafer to a suitable chemical solution that dissolves the photoresist. The resist layer, which has been protecting certain areas of the wafer and covering the regions where the metal was not intended to be deposited, is now removed. This solution cleans away the resist, leaving behind only the metal that was deposited in the desired regions, specifically on the gate field-plate areas.

As the photoresist is dissolved and washed away, the metal layer that was deposited during Step 11 remains intact in the defined patterns. This metal layer, which was deposited to a thickness of 100 to 400 nm, now serves as the gate field-plate. The gate structure has been thickened and widened due to the additional metal layer, and it overlaps the gate recess region, extending further towards the drain side. This design enhances the device's performance by providing better electric field control.

The completion of Step 12 results in the gate field-plate being fully formed and operational. It improves the stability and performance of the HEMT device, especially in high-frequency and high-power applications. With the resist fully removed, the wafer is now prepared for the next stages in the fabrication process, ensuring that the gate field-plate is in its final, functional form.

What is claimed is:

1. A circuitry for amplification, comprising:
a main amplifier comprising a first transistor:
an auxiliary amplifier comprising a second transistor; and
a single gate bias supply configured to provide a common gate voltage to both the first transistor of the main amplifier and the second transistor of the auxiliary amplifier, wherein the first transistor and the second transistor have different threshold voltages.

2. The circuitry as claimed in claim 1, wherein the first transistor and the second transistor are fabricated on a single semiconductor wafer.

3. The circuitry as claimed in claim 2, wherein the semiconductor wafer is a gallium nitride (GaN) wafer on any substrate, i.e. Silicon Carbide (SiC), Sapphire, Silicon or other such relevant substrates.

4. The circuitry as claimed in claim 1, wherein the first transistor and the second transistor are fabricated on single or separate semiconductor wafers.

5. The circuity as claimed in claim 4, wherein the first transistor is fabricated on a gallium nitride (GaN) wafer on any substrate and the second transistor is fabricated on a separate GaN wafer with the same or different substrate.

6. The circuity as claimed in claim 1, wherein the single gate bias supply is programmable to adjust the common gate voltage dynamically based on operational conditions, optimizing the amplifier's efficiency across varying power levels.

7. The circuitry as claimed in claim 1, wherein the threshold voltage of the first transistor and the threshold voltage of the second transistor are tailored to be distinct, thereby enabling the main amplifier and the auxiliary amplifier to operate in a coordinated manner when supplied with the common gate voltage from the single gate bias supply.

8. The circuitry as claimed in claim 1, wherein the threshold voltage of the second GaN transistor is tailored by controlled recess etching of a barrier layer.

9. The circuitry as claimed in claim 8, further comprising a thin gate dielectric layer applied after the controlled recess etching, wherein the thin gate dielectric layer has a thickness ranging from 1 nm to 30 nm, and, wherein, the gate dielectric material is selected from a group consisting of aluminium oxide (Al₂O₃), silicon nitride (SiN), silicon dioxide (SiO₂), hafnium oxide (HfO₂), or any combination thereof.

10. The circuitry as claimed in claim 1, wherein the threshold voltage of the first GaN transistor is tailored by applying a gate dielectric layer without recess etching of a barrier layer.

11. A method of manufacturing a circuitry for amplification, the method comprising:
forming a first transistor and a second transistor are fabricated on a single semiconductor wafer or on separate semiconductor wafers:
tailoring a first threshold voltage for the first transistor and a second threshold voltage for the second transistor; and
configuring a single gate bias supply to provide a common gate voltage to the gates of both transistors.

12. The method as claimed in claim 11, wherein step of forming the first transistor and the second transistor comprises fabricating both transistors on a single gallium nitride (GaN) wafer.

13. The method as claimed in claim 11, wherein the step of forming the first transistor and the second transistor comprises fabricating the two transistors on two wafers of same or different semiconductor wafers, wherein the first wafer should be a GaN wafer.

14. A Doherty power amplifier, comprising:
a main amplifier comprising a first high electron mobility transistor (HEMT):
an auxiliary amplifier comprising a second HEMT; and
a single gate bias supply configured to provide a common gate voltage to both the first HEMT of the main amplifier and the second HEMT of the auxiliary amplifier, wherein the first HEMT and the second HEMT have different threshold voltages,
wherein the first HEMT and the second HEMT are fabricated on the same wafer or on different wafers.

15. The amplifier as claimed in claim 14, further comprising:
a barrier layer selected from a group consisting of aluminium gallium nitride (AlGaN), indium aluminium nitride (InAlN), indium aluminium gallium nitride (InAlGaN), aluminium nitride (AlN), and scandium aluminium nitride (ScAlN).
